(19) United States
(12) Patent Application Publication
(10) Pub. No.: US 2009/0170247 A1
(43) Pub. Date: Jul. 2, 2009

(54) MAGNETIC PARTICLES FOR LOW TEMPERATURE CURE OF UNDERFILL

(76) Inventors: Linda A. SHEKHAWAT, Tucson, AZ (US); Gregory S. CONSTABLE, Chandler, AZ (US); Youzhi E. XU, Gilbert, AZ (US); Nisha ANANTHAKRISHNAN, Chandler, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/966,933

(22) Filed: Dec. 28, 2007

(51) Int. Cl. H01L 21/50

(52) U.S. Cl. 438/127; 257/E21.499

(57) ABSTRACT

Electronic devices and methods for fabricating electronic devices are described. One embodiment includes a method comprising providing a first body and a second body, and electrically coupling the first body to the second body using a plurality of solder bumps, wherein a gap remains between the first body and the second body. The method also includes placing an underfill material into the gap between the first body and the second body, the underfill material comprising magnetic particles in a polymer composition. The method also includes curing the underfill material in the gap by applying a magnetic field powered by alternating current, to induce heat in the magnetic particles, wherein the heat in the magnetic particles heats the polymer composition, and the magnetic field is applied for a sufficient time to cure the polymer composition. Other embodiments are described and claimed.

### RELATED ART

In certain conventional electronic assembly manufacturing procedures, a die and a substrate 12 are brought into electrical contact with one another using solder bumps. A reflow operation is carried out by heating to a temperature greater than the melting point of the solder, and a solder connection is made between the pads on the die and pads on the substrate. A gap remains between the die and the substrate. A material such as a polymer is then typically placed into the gap between the chip and substrate, as an underfill encapsulant.

FIG. 1 illustrates certain features of a conventional assembly manufacturing process. As illustrated in FIG. 1, a dispenser 16 such as a needle is positioned adjacent to a die 10 coupled to a substrate 12 through solder bumps 14. An underfill material 18 is dispensed on the substrate 12 next to the die attach area. The underfill material 18 may include a polymer, for example, an epoxy. With the application of heat, the underfill material 18 may be made to flow between the die 10 and substrate 12, using capillary action. When formed from a polymer epoxy, the underfill material 18 may then be cured by heating the assembly to a temperature of, for example, about 150° C. The cured underfill material 18 surrounds the solder bumps 14 and protects the bumps and connection between the die 10 and substrate 12, as well as assist in supporting the die 10 on the substrate 12.

### BRIEF DESCRIPTION OF THE DRAWINGS

Embodiments are described by way of example, with reference to the accompanying drawings, which are not drawn to scale, wherein:

FIG. 1 illustrates a side cross-sectional view of a conventional processing operation in which an underfill material is dispensed on a substrate;

FIGS. 2(A)-2(B) illustrate views of an assembly including a die coupled to a substrate, with an underfill material positioned between the die and substrate, in accordance with certain embodiments, with FIG. 2(A) illustrating the underfill material including a plurality of magnetic particles therein, and FIG. 2(B) illustrating the underfill during application of a magnetic field thereto, including the heating of the magnetic particles;

FIG. 3 illustrates a flow chart of operations in a process for forming an assembly using an underfill material including magnetic particles and applying a magnetic field to the underfill material, in accordance with certain embodiments; and

FIG. 4 illustrates an electronic system arrangement in which embodiments may find application.

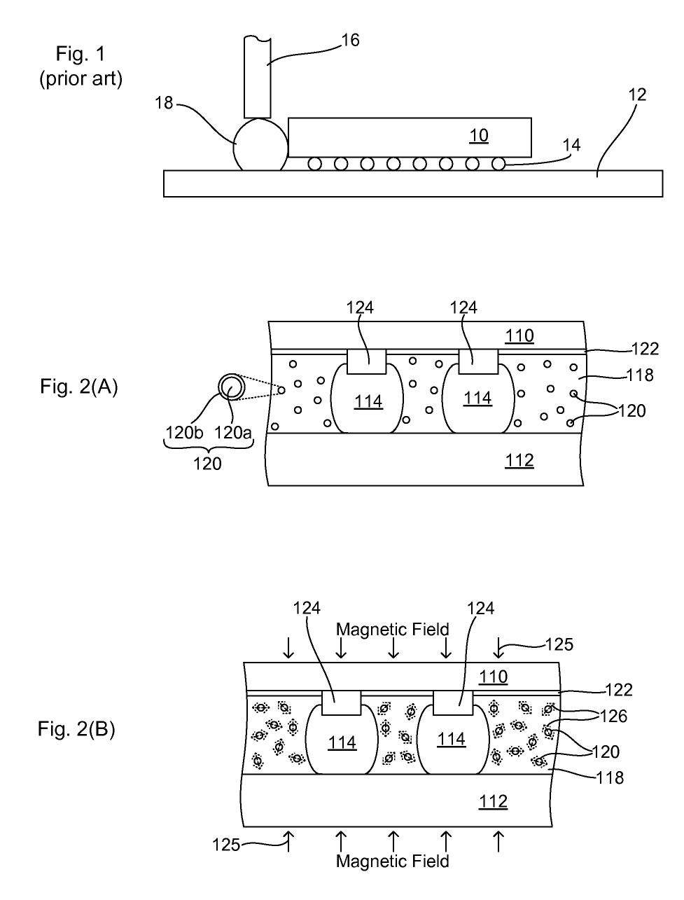

### DETAILED DESCRIPTION

Certain embodiments relate to the formation of electronic assemblies, in which the curing of the underfill material may be carried out at relatively low temperatures. In certain embodiments, the underfill material includes magnetic particles dispersed in a polymer composition such as an epoxy. A magnetic field is applied to the magnetic particles in the underfill, which causes particles to heat up. The heat from the particles is transmitted to the polymer portion of the underfill material and enables it to cure. Such curing can be carried out at a lower temperature than conventional methods of applying heat to an underfill material, such as oven heating. This is believed to be due to the heat being applied from within the underfill material, instead of from outside of the underfill material.

FIGS. 2(A)-2(B) illustrate views of an electronic assembly during several stages of processing, in accordance with certain embodiments. FIG. 2(A) illustrates the positioning of an underfill material 118 into a region between a body such as a die 110 and a body such as a substrate 112. The die 110 may include a passivation layer 122 and a plurality of bonding pads 124 thereon. The die 110 is electrically coupled to regions on the substrate 112 through solder 114 that is in contact with the bonding pads 124. The underfill material 118 may include a polymer matrix material containing a plurality of magnetic particles 120 dispersed therein. The polymer matrix material may in certain embodiments comprise a thermosetting resin, for example, an epoxy. Other materials such as fillers and additives may also be present in the underfill material 118.

The magnetic particles 120 may be surface treated with a coating thereon. As illustrated in the blown-up portion of FIG. 2(A), the magnetic particle 120 may include a core region 120a and a coating region 120b. Suitable core region 120a materials include particles including, but not limited to, cobalt, nickel, iron, Fe₃O₄, γ-Fe₂O₃, and other ferrites. The coating region 120b comprises an electrically insulating material, including, for example, polymer coatings and ceramic coatings. The coating region 120b acts to inhibit the magnetic particles from causing the underfill material 118 to become an electrically conductive medium. Suitable coating region 120b materials include, but are not limited to, poly(ethylene), and SiO₂. The coating region 120b may also include additional materials, for example, to inhibit agglomeration of the magnetic particles 120.

In certain embodiments, the magnetic particles 120 may be formed as discrete nanoparticles or larger particles comprised of a number of nanoparticles (for example, less than 10 nanoparticles). The magnetic particles may in certain embodiments each be up to about 50 nanometers in diameter (other sizes, for example, up to about 100 nanometers, are also possible) and dispersed in underfill formulations that include one or more of resins, amine cure agents, filler materials such as silica filler, and additives. The magnetic particles 120 may in certain embodiments be present up to about 10 percent by volume of the underfill material.

FIG. 2(B) illustrates a similar view as FIG. 2(A), with the magnetic particles 120 being subjected to a magnetic field 125 (indicated by solid arrows above and below the assembly) that induces heating and curing of the underfill material 118. In this embodiment, the magnetic field is generated using alternating current (AC). The magnetic field induces movement of the magnetic particles, causes them to vibrate back and forth, as indicated by the arrows 126 (in dotted lines) extending through the particles 120. The vibrations generate heat, which is transferred to the polymer portion of the underfill material 118, which may be, for example, an epoxy that may be cured at a relatively low curing temperature, such as about 80-90° C. By controlling the intensity of the magnetic field, the desired amount of heat may be quickly applied and controlled.

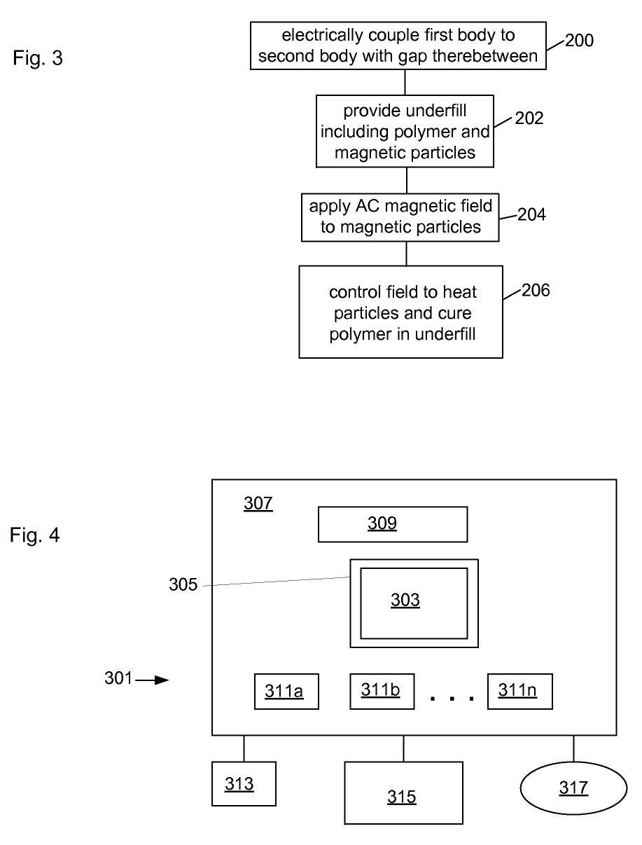

FIG. 3 is a flow chart showing a number of operations in accordance with certain embodiments. Box 200 is electrically coupling a first body (for example, a die), to a second body (for example, a package substrate), using a method such as, for example, a C4 (controlled collapse chip connection) process, in which a gap remains between the first body and the second body. Solder bumps may be used to make the electrical connection between the first body and the second body. Box 202 is providing an underfill material including a polymer, for example, an epoxy, having magnetic particles therein, such as described above in connection with FIGS. 2(A)-2(B). Box 204 is applying a magnetic field using AC power to heat the magnetic particles in the underfill positioned between the first body and the second body to a sufficient temperature so that the polymer matrix of the underfill begins to cure. Box 206 is controlling the intensity and time of application of the magnetic field so that heat from the magnetic particles causes the polymer matrix to cure. Various modifications to the above operations may be made.

Embodiments such as described above may have one or more of the following advantages, including: (1) providing a low temperature curing process; (2) reducing package warpage and reducing stresses in the underfill material due to thermal expansion mismatch, due to the lower temperatures seen by the assembly components during the curing process; (3) inhibiting micron sized filler settling issues in the underfill, due to the presence of particles having a size of, for example, up to about 100 nanometers; and (4) increasing the toughness of the underfill by the increased interfacial zone of the particles with the polymer matrix.

Assemblies including a substrate and die joined together as described in embodiment above may find application in a variety of electronic components, at various interconnection levels within the assembly. FIG. 4 schematically illustrates one example of an electronic system environment in which aspects of described embodiments may be embodied. Other embodiments need not include all of the features specified in FIG. 4, and may include alternative features not specified in FIG. 4.

The system 301 of FIG. 4 may include at least one central processing unit (CPU) 303. The CPU 303, also referred to as a microprocessor, may be a die which is attached to an integrated circuit package substrate 305, which is then coupled to a printed circuit board 307, which in this embodiment, may be a motherboard. The CPU 303 on the package substrate 305 is an example of an electronic device assembly that may be formed in accordance with embodiments such as described above, including an underfill material having magnetic particles therein. A variety of other system components, including, but not limited to memory and other components discussed below, may also include die and substrate structures formed in accordance with the embodiments described above.

The system 301 may further include memory 309 and one or more controllers 311a, 311b . . . 311n, which are also disposed on the motherboard 307. The motherboard 307 may be a single layer or multi-layered board which has a plurality of conductive lines that provide communication between the circuits in the package 305 and other components mounted to the board 307. Alternatively, one or more of the CPU 303, memory 309 and controllers 311a, 311b . . . 311n may be disposed on other cards such as daughter cards or expansion cards. The CPU 303, memory 309 and controllers 311a, 311b . . . 311n may each be seated in individual sockets or may be connected directly to a printed circuit board. A display 315 may also be included.

Any suitable operating system and various applications execute on the CPU 303 and reside in the memory 309. The content residing in memory 309 may be cached in accordance with known caching techniques. Programs and data in memory 309 may be swapped into storage 313 as part of memory management operations. The system 301 may comprise any suitable computing device, including, but not limited to, a mainframe, server, personal computer, workstation, laptop, handheld computer, handheld gaming device, handheld entertainment device (for example, MP3 (moving picture experts group layer—3 audio) player), PDA (personal digital assistant) telephony device (wireless or wired), network appliance, virtualization device, storage controller, network controller, router, etc.

The controllers 311a, 311b . . . 311n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 313 in accordance with a storage protocol layer. The storage protocol of the layer may be any of a number of known storage protocols. Data being written to or read from the storage 313 may be cached in accordance with known caching techniques. A network controller can include one or more protocol layers to send and receive network packets to and from remote devices over a network 317. The network 317 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. A method comprising:
providing a first body and a second body;
coupling the second body to the first body, wherein a gap remains between the second body and the first body;
placing an underfill material on the first body, the underfill material comprising magnetic particles in a polymer composition;
delivering at least part of the underfill material into the gap; and
curing the underfill material in the gap by applying a magnetic field to induce heat in the magnetic particles, wherein the heat in the magnetic particles heats the polymer composition, and the magnetic field is applied for a sufficient time to cure the polymer composition.

2. The method of claim 1, further comprising applying an alternating current to generate the magnetic field.

3. The method of claim 1, wherein the magnetic particles have a diameter of up to about 100 nanometers.

4. The method of claim 1, wherein the magnetic particles include a coating selected from the group consisting of polymers and ceramics.

5. The method of claim 1, wherein the polymer composition comprises an epoxy.

6. The method of claim 1, wherein the first body comprises a substrate and the second body comprises a semiconductor die.

7. The method of claim 1, wherein the curing the underfill material comprises heating the underfill material so that the second body reaches a temperature of no greater than 90 degrees Celsius.

8. The method of claim 1, wherein the magnetic particles make up no greater than 10 percent by volume of the underfill material.

9. A method comprising:
providing a first body and a second body;
electrically coupling the first body to the second body using a plurality of solder bumps, wherein a gap remains between the first body and the second body;
placing an underfill material into the gap between the first body and the second body, the underfill material comprising magnetic particles in a polymer composition; and
curing the underfill material in the gap by applying an magnetic field powered by alternating current, to induce heat in the magnetic particles, wherein the heat in the magnetic particles heats the polymer composition, and the magnetic field is applied for a sufficient time to cure the polymer composition.

10. The method of claim 9, wherein the magnetic particles have a diameter of up to about 100 nanometers.

11. The method of claim 9, wherein the magnetic particles include a coating selected from the group consisting of polymer and ceramic materials.

12. The method of claim 9, wherein the polymer composition comprises an epoxy.

13. The method of claim 9, wherein the curing the underfill material comprises heating the underfill material so that the second body reaches a temperature of no greater than 90 degrees Celsius.

14. The method of claim 9, wherein the magnetic particles make up no greater than 10 percent by volume of the underfill material.
